(19) United States
(12) Patent Application Publication
(10) Pub. No.: US 2016/0329534 A1
(43) Pub. Date: Nov. 10, 2016

(54) POLYMER COATINGS FOR METAL SURFACES

(71) Applicant: ZPower, LLC, Camarillo, CA (US)

(72) Inventors: Scott FLYNN, Camarillo, CA (US); Glen ROBLES, Santa Maria, CA (US); Herbert V. WEIGEL, II, Oakland, CA (US)

(21) Appl. No.: 15/111,196

(22) PCT Filed: Jan. 13, 2015
(86) PCT No.: PCT/US2015/011087

§ 371 Date: Jul. 13, 2016

Related U.S. Application Data
(60) Provisional application No. 61/927,006, filed on Jan. 14, 2014.

(51) Int. Cl. H01M 2/02; H01M 10/26; H01M 10/32; B41J 2/01; C23C 16/56

(52) U.S. Cl. CPC H01M 2/0292; B41J 2/01; C23C 16/56; H01M 2/0222; H01M 2/026; H01M 10/32; H01M 10/26; H01M 2220/30

(57) ABSTRACT

The present invention provides formulations, apparatuses, and methods for forming durable polymer coatings on metallic surfaces. These polymer coatings are formulated to include an epoxy resin, a photoinitiator, and a cross-linking agent. Such polymer coatings are tintable and can optionally comprise additives such as fillers.

### CROSS REFERENCE TO RELATED APPLICATION

This PCT application claims the benefit of U.S. provisional application No. 61/927,006, filed on Jan. 14, 2014. This document is hereby incorporated by reference in its entirety.

### FIELD OF THE INVENTION

The present invention is concerned with methods for coating a metallic surface, formulations for such coatings, and apparatuses that perform coating processes.

### BACKGROUND OF THE INVENTION

Historically, metal surfaces and metal plated surfaces must undergo extensive treatments prior to the application of polymeric coatings or inks. For example, metal surfaces are traditionally pre-treated with hydrophobic or other surface treatments prior to ink jet printing.

In other examples, polymeric coatings for metal surfaces lack durability when subjected to environmental conditions such as sunlight, solvents, and/or surfactants.

### SUMMARY OF THE INVENTION

The present invention relates to formulations, methods, and apparatuses for generating durable polymeric coatings on metallic surfaces (e.g., the external surface of a battery housing or battery can).

In one aspect, the present invention provides a method of coating at least a portion of a metallic battery housing with a polymer material coating comprising applying a polymer material to an external surface of the metallic housing; shaping the polymer coating on the surface of the housing to form a coating on at least a portion of the external surface; applying an ink to the coating; and at least partially curing the coating by applying UV radiation to the coating, wherein the polymer material comprises an epoxy resin, a cross-linking agent, and a photoinitiator; and wherein the ink is applied to the coating prior to or concurrent with the curing of the coating.

In some embodiments, the polymer material further comprises a tint.

In some embodiments, the epoxy resin comprises bisphenol A epoxy resin, bisphenol F epoxy resin, novolac epoxy resin, aliphatic epoxy resin, glycidylamine epoxy resin, or any combination thereof.

In some embodiments, the cross-linking agent comprises tetraethylene glycol dimethacrylate, N,N-dimethyl acrylamide, isobornyl acrylate, urethane methacrylate, hexanediol diacrylate, di-trimethylolpropane tetra-acrylate, bisphenol A epoxy acrylate, carboxylated polyester methacrylate, aliphatic urethane acrylate, poly(acrylonitrile-co-buradines)-dicarboxy, polybutadiene dicarboxy terminated, isooctyl acetate, poly(acrylic acid), aliphatic urethane acrylate oligomer, difunctional aliphatic urethane acrylate oligomer, urethane diacrylate oligomer blended with isobornyl acrylate, or any combination thereof.

In some embodiments, the photoinitiator comprises 2,2-dimethoxy-2-phenyl-acetophenone, 3,4-dimethylbenzophenone, 2-hydroxy-2-methyl-1-phenyl-propan-1-one, α-amino ketone, 1-hydroxy-cyclohexyl-phenyl ketone, benzophenone, benzoin ethyl ether, benzoin ethyl ether with cyclodextrin, or any combination thereof.

In some embodiments, the polymer material is applied to the metallic housing under a layer of inert gas.

In some embodiments, the inert gas is selected from the group consisting of nitrogen gas, argon gas, carbon dioxide gas, and any combination thereof.

Some embodiments further comprise rotating the housing about a central axis and applying the polymer material to the outer circumference of the rotating housing.

In some embodiments, the shaping of the polymer material comprises applying an edge to the polymer material on the rotating housing to shape the polymer material into a coating that covers at least a portion of the outer circumference of the housing.

In some embodiments, the ink is applied to the coating using an ink jet.

In some embodiments, the ink is applied to the polymer material before the coating is substantially cured.

Some embodiments further comprise applying UV radiation to the coating for a period of from about 10 s to about 10 min (e.g., from about 10 s to about 5 min, from about 10 s to about 1 min, or from about 15 s to about 1 min).

In some embodiments, the UV radiation is substantially free of UV-B or UV-C radiation.

In some embodiments, the polymer material further comprises a filler. For example, the polymer material further comprises a filler comprising silicone dioxide, calcium carbonate, calcium hydroxide, hydrophobic silica, bentonite, polyacrylic acid, sand, hydroxyethyl cellulose, methylcellulose, dragonite, or any combination thereof.

In some embodiments, the polymer material further comprises an adhesion promoter.

In some embodiments, the polymer material further comprises a solvent. For example, the polymer material comprises a solvent comprising diacetone alcohol, butylacetate, or any combination thereof.

In some embodiments, the ink comprises a color that contrasts with a color of the polymer material coating under visible light.

Another aspect of the present invention provides an apparatus for applying a polymeric coating to an external metallic surface of a battery housing comprising a holder; an applicator; a reservoir that stores uncured polymer material and fluidly connects to the applicator; a wiper comprising an edge; a printer; a UV lamp; and a gas outlet, wherein the holder is configured to rotate the battery housing about a central axis; the wiper is movable with respect to the central axis and configured to shape polymer material that is applied to the surface of the battery housing; and the gas outlet is configured to generate a layer of inert gas between the applicator and the battery housing.

In some embodiments, the applicator is movable with respect to the central axis and configured to apply polymer material to at least a portion of the battery housing.

In some embodiments, the applicator is selected from the group consisting of a syringe, an extruder, a sprayer, a roller, and a sponge.

In some embodiments, the applicator is configured to apply a bead of polymer material to the surface of the battery housing.

In some embodiments, the UV lamp, the reservoir, the applicator, or any combination thereof further comprises a radiation shield.

In some embodiments, the wiper further comprises a wipe material. In some of these embodiments, the wipe material is disposed between the edge of the wiper and the battery housing. In addition, in some instances, the wipe material further comprises a woven or non-woven film.

In some embodiments, the reservoir comprises a storage chamber that is substantially free of oxygen gas.

In some embodiments, the printer is an inkjet printer.

Another aspect of the present invention provides a rechargeable electrochemical cell comprising an anode comprising zinc; a cathode comprising silver oxide; an electrolyte comprising an alkali metal hydroxide; a cylindrical metallic housing having a central axis and an outer circumference; and a coating that covers at least a portion of the outer circumference of the housing, wherein the coating is generated by applying a polymer material to an external surface of the metallic housing; shaping the polymer material on the surface of the housing to form a coating; applying an ink to the coating; and curing the coating under ultraviolet radiation, wherein the polymer material comprises an epoxy resin, a cross-linking agent, a photoinitiator, and a tint; and wherein the ink is applied to the coating prior to or concurrent with the curing of the coating.

### BRIEF DESCRIPTION OF THE DRAWINGS

The following figures are provided by way of example and are not intended to limit the scope of the claimed invention.

FIG. 1 is an illustration of the application of a bead of polymer material onto a metallic battery housing according to one or more embodiments of the present invention.

FIG. 2 is an illustration of an edge shaping two beads of polymer material into a coating according to one or more embodiments of the present invention.

FIG. 3 is a cross-sectional view of a battery that is coated according to one or more embodiments of the present invention.

FIG. 4 is an illustration of an applicator and reservoir according to one or more embodiments of the present invention.

FIG. 5 is a side view of a wiper in accordance with one or more embodiments of the present invention.

FIG. 6 is a top view of a wiper in accordance with one or more embodiments of the present invention.

FIG. 7 is a side view of an ink jet in accordance with one or more embodiments of the present invention.

FIG. 8 is a front view of a polymer material coating apparatus according to one or more embodiments of the present invention.

FIG. 9 is a depiction of XR41 and XR48 batteries according to one or more embodiments of the present invention.

FIG. 10 is a depiction of XR41 and XR48 batteries according to one or more embodiments of the present invention.

### DETAILED DESCRIPTION OF THE INVENTION

The present invention provides a novel method for coating an external metallic surface (e.g., nickel plated stainless steel) of a battery housing comprising applying a polymer material to the external metallic surface; shaping the polymer material on the external metallic surface to form a coating; applying an ink to the coating; and curing the coating under ultraviolet radiation, wherein the polymer material comprises an epoxy resin, a cross-linking agent, a photoinitiator, and an optional tint; and wherein the ink is applied to the coating prior to or concurrent with the curing of the coating.

The present invention also provides an apparatus for applying coatings to an external metallic surface of a battery housing and an electrochemical cell (e.g., a battery) that comprises a polymer coating.

### I. DEFINITIONS

As used herein, the following definitions shall apply unless otherwise indicated.

As used herein, the term “battery” encompasses electrical storage devices comprising one electrochemical cell (e.g., a button cell, a coin cell, or the like) or a plurality of electrochemical cells. A “secondary battery” is rechargeable, whereas a “primary battery” is not rechargeable. For secondary batteries of the present invention, a battery anode is designated as the negative electrode during discharge, and as the positive electrode during charge.

As used herein, an “electrolyte” refers to a substance that behaves as an ionically conductive medium. For example, the electrolyte facilitates the mobilization of anions and cations in the cell. Electrolytes include mixtures of materials such as aqueous solutions of alkaline agents. Some electrolytes also comprise additives such as buffers. For example, an electrolyte comprises a buffer comprising a borate or a phosphate. Exemplary electrolytes include, without limitation, aqueous KOH, aqueous NaOH, or the liquid mixture of KOH in a polymer.

As used herein, an “anode” is an electrode through which (positive) electric current flows into a polarized electrical device. In a battery or galvanic cell, the anode is the negative electrode from which electrons flow during the discharging phase in the battery. The anode is also the electrode that undergoes chemical oxidation during the discharging phase. However, in secondary, or rechargeable, cells, the anode is the electrode that undergoes chemical reduction during the cell's charging phase. Anodes are formed from electrically conductive or semiconductive materials, e.g., metals, metal oxides, metal alloys, metal composites, semiconductors, or the like. Common anode materials include Si, Sn, Al, Ti, Mg, Fe, Bi, Zn, Sb, Ni, Pb, Li, Zr, Hg, Cd, Cu, LiC₆, mischmetals, alloys thereof, oxides thereof, or composites thereof. Anode materials such as zinc may even be sintered.

Anodes may have many configurations. For example, an anode may be configured from a conductive mesh or grid that is coated with one or more anode materials. In another example, an anode may be a solid sheet or bar of anode material.

As used herein, a “cathode” is an electrode from which (positive) electric current flows out of a polarized electrical device. In a battery or galvanic cell, the cathode is the positive electrode into which electrons flow during the discharging phase in the battery. The cathode is also the electrode that undergoes chemical reduction during the discharging phase. However, in secondary or rechargeable cells, the cathode is the electrode that undergoes chemical oxidation during the cell's charging phase. Cathodes are formed from electrically conductive or semiconductive materials, e.g., metals, metal oxides, metal alloys, metal composites, semiconductors, or the like. Common cathode materials include Mn, MnO, Mn₂O₃, MnO₂, HgO, Hg₂O, Ag, Ag₂O, AgO, CuO, CdO, NiOOH, Pb₂O₄, PbO₂, LiFePO₄, Li₃V₂(PO₄)₃, V₆O₁₃, V₂O₅, Fe₃O₄, Fe₂O₃, MnO₂, LiCoO₂, LiNiO₂, LiMn₂O₄, or composites thereof. Cathode materials such as Mn, MnO, MnO₂, Mn₂O₃, Mn₃O₄, and MnOOH, may even be sintered.

Cathodes may also have many configurations. For example, a cathode may be configured from a conductive mesh that is coated with one or more cathode materials. In another example, a cathode may be a solid sheet or bar of cathode material.

Batteries and battery electrodes are denoted with respect to the active materials in the fully charged state. For example, a zinc-manganese battery comprises an anode comprising zinc and a cathode comprising a manganese powder (e.g., MnO₂). Nonetheless, more than one species is present at a battery electrode under most conditions. For example, a zinc electrode generally comprises zinc metal and zinc oxide (except when fully charged), and a manganese powder electrode usually comprises MnO, Mn₂O₃, Mn₃O₄ and/or MnO₂ and manganese metal (except when fully discharged).

As used herein, the term “oxide” applied to alkaline batteries and alkaline battery electrodes encompasses corresponding “hydroxide” species, which are typically present, at least under some conditions.

As used herein, the term, “powder” refers to a dry, bulk solid composed of a plurality of fine particles that may flow freely when shaken or tilted.

As used herein, the terms “first” and/or “second” do not refer to order or denote relative positions in space or time, but these terms are used to distinguish between two different elements or components. For example, a first separator does not necessarily proceed a second separator in time or space; however, the first separator is not the second separator and vice versa. Although it is possible for a first separator to precede a second separator in space or time, it is equally possible that a second separator precedes a first separator in space or time.

As used herein, the term “polymer material” refers to a cured or uncured material that comprises a polymer, a copolymer, an oligomer, or two or more monomers.

### II. METHODS AND APPARATUSES

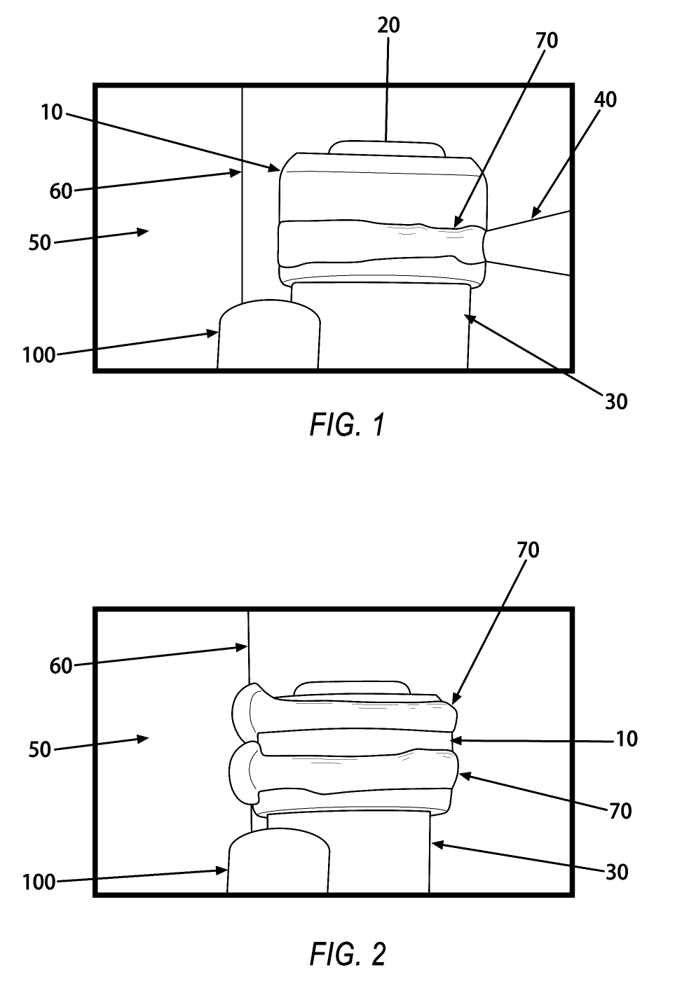

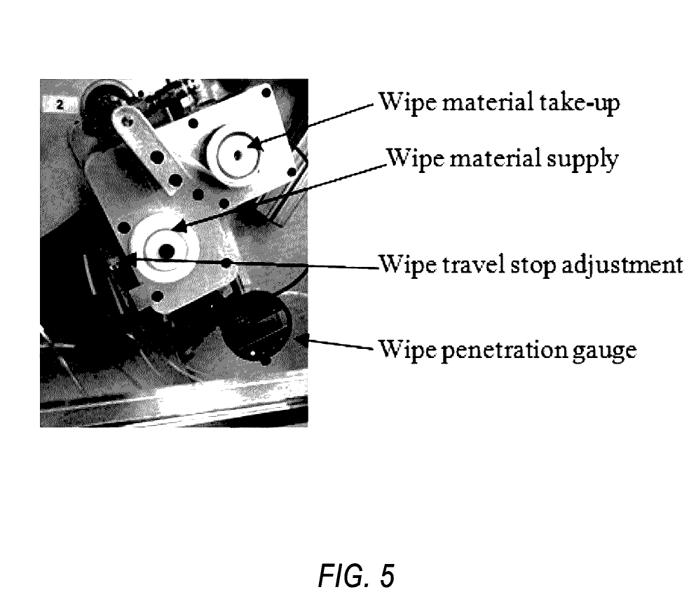

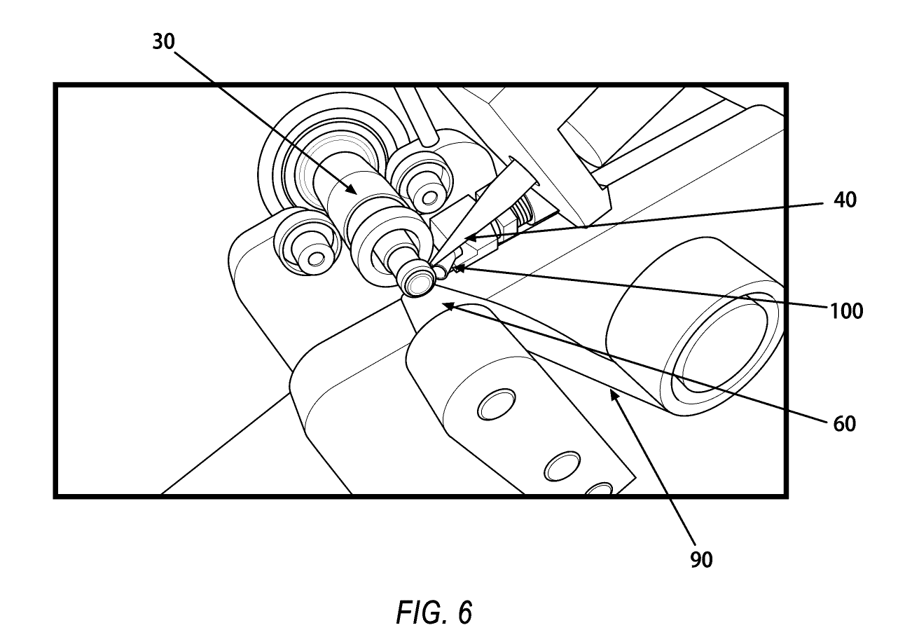

Referring to FIGS. 1-8, the present invention provides a method of coating at least a portion of a battery housing with a polymer coating material comprising applying the polymer material (e.g., a substantially uncured polymer material or a flowable polymer material) to a metallic external surface of the battery housing 10; shaping the polymer material on the surface of the housing to form a coating 80 on at least a portion of the external surface; applying an ink to the coating; and at least partially curing the coating by applying ultraviolet radiation to the coating, wherein the polymer material comprises an epoxy resin, a cross-linking agent, and a photoinitiator; and wherein the ink is applied to the coating prior to or concurrent with the curing of the coating.

In some embodiments, the polymer material further comprises a tint.

In some embodiments, the metallic external surface of the housing comprises iron, nickel, chromium, or any combination thereof. For example, the external surface of the housing comprises nickel-plated stainless steel.

Polymer materials suited for this method comprise an epoxy resin, a cross-linking agent, a photoinitiator, and an optional tint. These polymer materials can be loaded into a syringe, brush, roller, sprayer, or other applicator and applied to a surface. The polymer material is photo-curable when exposed to UV radiation. In addition, in some embodiments, the polymer material comprises sufficient viscosity (e.g., from about 20,000 cP to about 60,000 cP or from about 25,000 cP to about 55,000 cP) at about room temperature (e.g., about 60° F. to about 80° F.) such that dripping is reduced when the polymer material is applied to the metallic surface of the battery housing.

In some embodiments, the epoxy resin remains substantially uncured when mechanically combined with a cross-linking agent, a photoinitiator, and a tint in a reduced oxygen (i.e., O₂ gas) environment. For example, the environment comprises less than about 10% (e.g., less than about 7.5%, less than about 5%, less than about 2%, or less than about 1%) of O₂.

In other embodiments, the epoxy resin comprises bisphenol A epoxy resin, bisphenol F epoxy resin, novolac epoxy resin, aliphatic epoxy resin, glycidylamine epoxy resin, or any combination thereof. Such epoxy resins are commercially available from manufactures such as Dow Chemical Company, (e.g., bisphenol A epoxy resin, bisphenol F epoxy resin, novolac epoxy resin), West Marine, Inc. (e.g., aliphatic epoxy resin), and Huntsman International LLC (e.g., glycidylamine epoxy resin).

In some embodiments, the cross-linking agent forms chemical bonds with the side chains of the epoxy resin polymer backbone upon exposure to UV radiation in the presence of a photoinitiator.

In some embodiments, the cross-linking agent comprises tetraethylene glycol dimethacrylate, N,N-dimethyl acrylamide, isobornyl acrylate, urethane methacrylate, hexanediol diacrylate, di-trimethylolpropane tetra-acrylate, bisphenol A epoxy acrylate, carboxylated polyester methacrylate, aliphatic urethane acrylate, poly(acrylonitrile-co-buradines)-dicarboxy, polybutadiene dicarboxy terminated, isooctyl acetate, poly(acrylic acid), aliphatic urethane acrylate oligomer, difunctional aliphatic urethane acrylate oligomer, urethane diacrylate oligomer blended with isobornyl acrylate, or any combination thereof.

Photoinitiators useful in the methods of the present invention are substantially inactive in the absence of UV radiation. In some embodiments, the photoinitiator is a compound that mediates polymerization reactions when exposed to UV radiation.

In some embodiments, the photoinitiator comprises 2,2-dimethoxy-2-phenyl-acetophenone, 3,4-dimethylbenzophenone, 2-hydroxy-2-methyl-1-phenyl-propan-1-one, α-amino ketone, 1-hydroxy-cyclohexyl-phenyl ketone, benzophenone, benzoin ethyl ether, benzoin ethyl ether with cyclodextrin, or any combination thereof.

In some methods of the present invention, the polymer material can optionally include a tint. Tints useful in the methods of the present invention are substantially inert when mechanically combined with the epoxy resin, cross-linking agent, and photoinitiator. Tints may include any color or combination of colors. For example, a yellow tint, a blue tint, and a white tint can be combined in sufficient quantities to generate a green tint. Tints can comprise a powder form in the absence of a fluid carrier.

In some embodiments, the polymer material further comprises a filler. For example, polymer material comprises a filler, and the filler comprises silicone dioxide, calcium carbonate, calcium hydroxide, hydrophobic silica, bentonite, polyacrylic acid, sand, hydroxyethyl cellulose, methylcellulose, dragonite, or any combination thereof.

In some embodiments, the polymer material further comprises an adhesion promoter. For example, the polymer material 70 further comprises an adhesion promoter comprising a solvent. In other instances, the solvent comprises diacetone alcohol, butylacetate, or any combination thereof.

Referring to FIGS. 1 and 2, in some embodiments, the battery housing 10 is cylindrical and comprises a metallic external surface. In some embodiments, the polymer material 70 is applied to at least a portion of the circumference of the cylindrical housing. In some of these embodiments, the battery housing 10 is rotated about a central axis 20 by a rotator 30, and an applicator 40 applies polymer material 70 to at least a portion of the circumference of the rotating battery housing 10. In some embodiments, the rotation is clockwise, while in other embodiments, the rotation is counter-clockwise.

In some embodiments, the applicator 40 applies the polymer material 70 to the circumference of the battery housing 10 under a layer of inert gas that is supplied by gas outlet 100. In some embodiments, the inert gas comprises helium gas, nitrogen gas, argon gas, or any combination thereof. In some embodiments, the gas outlet 100 may supply carbon dioxide or carbon dioxide in combination with one or more inert gases. In other embodiments, the gas outlet 100 is configured such that a stream of inert gas contacts the applied polymer material 70 and the applicator 40. In some examples, the rotator 30 rotates the battery housing 10 at about 5 rpm or more (e.g., about 5 rpm to about 30 rpm). In other examples, the applicator 40 is fixed with respect to the central axis 20 while the polymer material 70 is applied to the metallic external surface.

A wiper 50 comprising an edge 60 is positioned to shape the uncured polymer material 70 that was applied to the battery housing 10 by the applicator 40. Referring to FIGS. 2, 5, and 6, a wiper 50 comprising an edge 60 is positioned to shape the uncured polymer material 70 that was applied to the circumference of the battery housing 10 by the applicator 40. The edge 60 contacts the uncured polymer material 70 on the external surface of the cylindrical battery housing 10 and spreads the uncured polymer material 70 along the length of the cylindrical battery housing 10. In some embodiments, the edge 60 is configured to remove excess polymer material 70, for instance from the circumference of the battery housing 10.

In some embodiments, the edge 60 is configured to modify the thickness of the polymer material 70 on the circumference of the battery housing 10 so that the outer diameter 75 of the battery, including the polymer material 70 is substantially uniform and sized to correspond with standardized battery housing dimensions, e.g., XR41 cell dimensions or XR48 cell dimensions. In some embodiments, the wiper 50 comprises a wipe material 90 that comprises a film (e.g., a woven or non-woven film). In automated processes, the wipe material 90 comprises a film that is configured as belt, wherein the film contacts freshly applied polymer material 70 at the edge of the wiper 50, and the film advances between a plurality of rollers so that fresh wipe material 90 is used for each battery housing 10 coating.

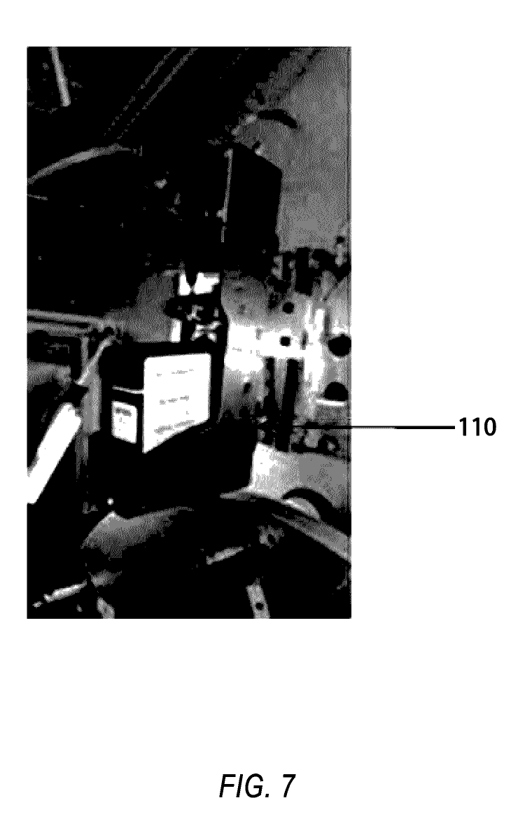

Following the shaping of the polymer material 70, an ink is applied to the polymer material 70. Referring to FIG. 7, in some embodiments, an ink jet 110 applies ink to the polymer material 70. In some embodiments, the ink is applied to the polymer material 70 when the polymer material 70 is at least partially uncured.

The coated polymer material 70 is cured upon exposure to radiation over a period. Radiation can be applied to the coating of polymer material 70 before, during, or after the application of the ink. In some embodiments, radiation is applied to the polymer material 70 after the ink is applied to the polymer material 70. In some embodiments, a UV lamp generates UV radiation that is directed to, or applied to, the uncured or partially cured polymer material 70. In some embodiments, UV radiation is applied to the polymer material 70 for a time of about 5 s to about 10 min. In some embodiments, the UV radiation is substantially free of UV-B or UV-C radiation.

In one aspect, the present invention provides an apparatus for performing the coating methods of the present invention. In one embodiment, the apparatus comprises a rotator 30 that rotates a cylindrical battery housing 10 about its central axis 20; an applicator 40; a reservoir 120 that stores polymer material 70 (e.g., uncured polymer material 70 or flowable polymer material 70) and fluidly connects to the applicator 40; a wiper 50 comprising an edge 60; a printer; a UV radiation source; and a gas outlet 100, wherein the wiping edge 60 is movable with respect to the rotator 30 and configured to shape the polymer material 70 that is applied to the circumference or external surface of the rotating battery housing 10; the gas outlet 100 is configured to generate a layer of inert gas by directing a stream of inert gas at one or more of the applicators 40, the battery housing 10, the wiper 50, the rotator 30, or any combination thereof; and ink jet printer is configured to apply ink to the circumference of the battery housing 10 that is coated with the polymer material 70.

In some embodiments, the apparatus comprises one applicator 40. In some embodiments, the apparatus comprises between one and ten applicators 40. In some embodiments, each applicator 40 is accompanied by at least one gas outlet 100. In some embodiments, a single gas outlet 100 may supply sufficient inert gas to one to three applicators 40.

In some embodiments, the rotator 30 is configured to hold a cylindrical battery housing 10 and rotate the housing 10 about its central axis 20 such that the external surface of the circumference of the cylindrical housing is exposed. In some embodiments, the rotator 30 comprises an electric motor that spins the cylindrical battery housing 10. In some embodiments, the rotator 30 comprises a magnet that magnetically holds the cylindrical battery housing 10. In other embodiments, the rotator 30 rotates the battery housing 10 during the application of the polymer material 70 to its circumference or external surface and during the wiping of the polymer material 70 to form the coating 80. In addition, in some embodiments, the rotator 30 also rotates the battery housing 10 when ink is applied to the polymer material 70 or to the coating 80. In some embodiments, the ink is applied by an inkjet printer.

In some embodiments, the apparatus comprises a plurality of rotators 30, wherein each rotator 30 can be configured as described above, and is also configured to be movable with respect to one or more other components (e.g., the applicator 40, the radiation source, the wiper 50, or the like) of the apparatus, so that a plurality of battery housings 10 can undergo assembly line-type processing by the apparatus sequentially.

In some embodiments, the apparatus comprises an applicator 40 that is configured to apply polymer material 70 to the exposed rotating surface of the cylindrical battery housing 10. In some embodiments, the applicator 40 comprises a tip (e.g., pipette tip, needle, nozzle, or the like) that applies a bead of polymer material 70 to the rotating surface of the battery housing 10. In other embodiments, the applicator 40 is configured to be movable with respect to the central axis 20. For instance, the applicator 40 or applicator tip moves toward the rotating surface of the battery housing 10 to apply a bead of the polymer material 70. Once the bead of polymer material 70 is applied to the surface of the battery housing 10, the applicator 40 or applicator tip moves away from the battery housing 10 that is now coated with the bead of polymer material 70.

Applicators useful in the methods and apparatuses of the present invention can apply a flowable polymer material 70 to at least a portion of a rotating surface of a cylindrical battery housing 10. In some embodiments, the applicator 40 comprises a syringe, an extruder, a sprayer, a brush, a roller, a sponge, or the like. In other embodiments, the applicator 40 fluidly connects with a reservoir 120 that feeds the polymer material 70 to the applicator or the applicator tip. In some embodiments, the reservoir 120 and the applicator 40 comprise a radiation shield that substantially protects the polymer material 70 from exposure to UV radiation while the polymer material is within the reservoir 120, the applicator 40, and the applicator tip.

Reservoirs 120 useful in the methods and apparatuses of the present invention can store the polymer material 70. In some embodiments, the polymer material 70 is stored as a flowable powder within a reservoir 120. In some embodiments, the polymer material 70 is stored as a liquid solution within a reservoir 120. In some embodiments, the polymer material 70 is stored as a semi-solid within a reservoir 120. In some embodiments, the reservoir 120 comprises a storage chamber that is substantially free of oxygen gas (O₂). In addition, in some embodiments, the reservoir 120 comprises a radiation shield that substantially protects the polymer material 70 contained therein from exposure to UV radiation.

In some embodiments, the applicator 40, the reservoir 120, or both comprise a radiation shield that reduces the exposure of the polymer material 70 to radiation that is generated by the radiation source (e.g., a UV lamp).

Wipers 50 useful in the methods and apparatuses of the present invention comprise an edge 60 that is configured to shape the polymer material 70 (e.g., the substantially uncured polymer material) that is applied (e.g., as a bead) to the circumference of the rotating battery housing 10. In some embodiments, the wiper 50 comprises an optional wipe material 90, such as any of the wipe materials described above, which is disposed between the edge of the wiper 50 and the polymer material 70 on the circumference of the battery housing 10. In other embodiments, the wipe material comprises a woven or non-woven film. In addition, in some embodiments, the wipe material comprises one or more adhesive surfaces (e.g., the wipe material comprises a tape with one or more adhesive surfaces).

In some embodiments, the wiper edge 60 is movable with respect to the central axis 20. For example, the wiper edge 60 may be movable such that there is an adjustable distance between the edge 60 and the circumference of the battery housing 10.

In some embodiments, an ink jet printer applies ink to the coating of polymer material 70 before the coating is substantially cured, or before the coating is exposed to UV radiation. In other embodiments, the ink jet printer applies ink to the coating of polymer material 70 as the polymer material 70 is being cured, i.e., application of the polymer coating 70 concurrently with exposure to UV radiation. In some embodiments, the ink comprises a color that contrasts from the color of the polymer material 70 coating under visible light, i.e., the color contrast is observable by the human eye. In some embodiments, the ink may be readable by a human or a suitable electronic device. In other embodiments, the ink jet is configured to apply ink to the substantially uncured polymer material 70 coating while the rotator 30 rotates the cylindrical battery housing 10 about its central axis. In other embodiments, the ink jet is configured to move circumferentially around the battery housing 10 as ink is applied to the circumference of the battery housing 10. In still other embodiments, both the rotator 30 and the ink jet are configured to simultaneously or sequentially move as the ink is applied to the polymer material 70.

In some embodiments, the radiation applied to the coating of polymer material 70 comprises UV radiation. In some embodiments, the source of this UV radiation is a UV lamp. In addition, in some embodiments, the radiation source, e.g., a lamp, further comprises a shield or hood that directs the light output towards the battery housing 10 and reduces the exposure of the applicator 40 and reservoir 120 to UV radiation.

### III. EXAMPLES

A general procedure for formulating and coating a polymer material 70 onto a metallic surface of a battery housing 10 is described herein. The procedure shown and described herein is not intended, nor should it be construed, to limit the scope of the claims in any manner whatsoever. Those skilled in the art will be able to recognize modifications of the disclosed procedure and to devise alternate methods based on the disclosures herein; all such modifications and alternate procedure are within the scope of the claims.

### Example 1

### General Polymer Material Formulations

In a container, liquid cross-linking agent (e.g., a monomer or oligomer) (5-30%) and a photoinitiator (1-10%) were mixed together to form a first mixture, i.e., mixture 1. In another container, tint (1-5%), fillers (1-10%), and a solvent/solvent mixture (5-15%) were mixed together to form a second mixture, i.e., mixture 2. The separate mixtures were stirred independently using a FlackTek SpeedMixer DAC150FVZ that allowed thorough mixing without introducing air into the system. An epoxy resin (30-80%), mixture 1, and mixture 2 were combined and mixed together using a FlackTek SpeedMixer DAC150FVZ at 2000 rpm for 2 minutes to yield the polymer material 70. In some instances, a commercially available polymer material formulations such as Emcast (commercially available from Electronic Materials, Inc.), Permabond (commercially available from Permabond LLC), Locite (commercially available from Henkel Corporation), and Dymax (commercially available from Dymax Corporation) was used.

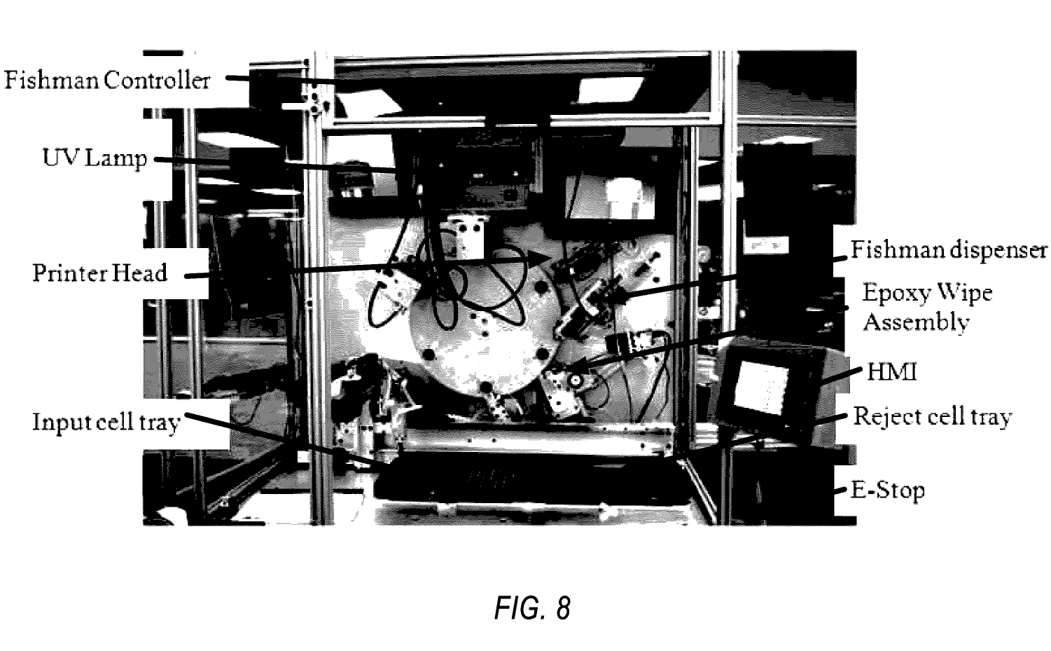

Once prepared, the polymer material 70 was used within 72 hours and found to be good for at least 60 days. The polymer material, in a liquid form, was loaded into a syringe dispenser (Fishman LDS9000 airless applicator) and subsequently applied to the rotating battery housing 10 under a layer of nitrogen using the apparatus depicted by FIG. 8. The outer surface of the battery housing comprised a nickel/stainless steel alloy, and the exposed surface was nickel. Depending on the height of the cell, 1 to 3 beads of polymer material coating were applied to the cell. For smaller cell sizes, e.g., XR41 cells, one bead of coating was used, whereas for larger cell sizes, e.g., XR48 cells, two beads of coating were used.

Once applied, the polymer material was shaped and smoothed to the desired diameter using a wipe material (e.g., Scotch Magic tape from 3M with a sticky side up). As the cell was rotating, the wipe material was, at times, pulled away from the cell to remove excess polymer material. The wipe material manipulated the applied polymer material around the battery housing to produce a coated cell. Manipulation of the wipe material allows a user to adjust the shape and size of the polymer material coating. How the wipe material is used ultimately determines the thickness of the polymer material coating and determines the outer diameter of the coated cell.

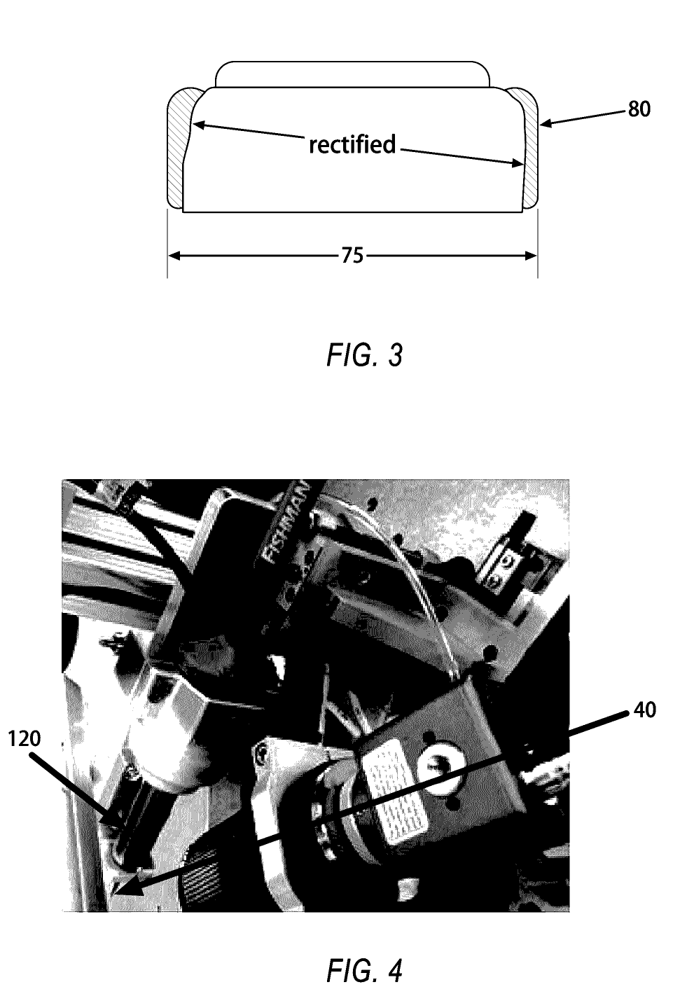

Referring now to FIG. 3, one of the functions of the polymer coating is to correct the geometry of the cells, e.g. to reproduce a smooth, cylindrical shape. For the XR41 cells, about 0.0056 g to about 0.0089 g of polymer material coating was needed to form an outer diameter of desired length. On average, about 0.0065 g of the polymer material coating was necessary to prepare an XR41 cell with a desirable outer diameter and coating thickness. For XR48 cells, about 0.01117 g to about 0.0136 g of polymer material coating was used to form a cell with an outer diameter of desired length. On average, about 0.0124 g of the polymer material coating yielded an XR48 cell having a desirable outer diameter and coating thickness.

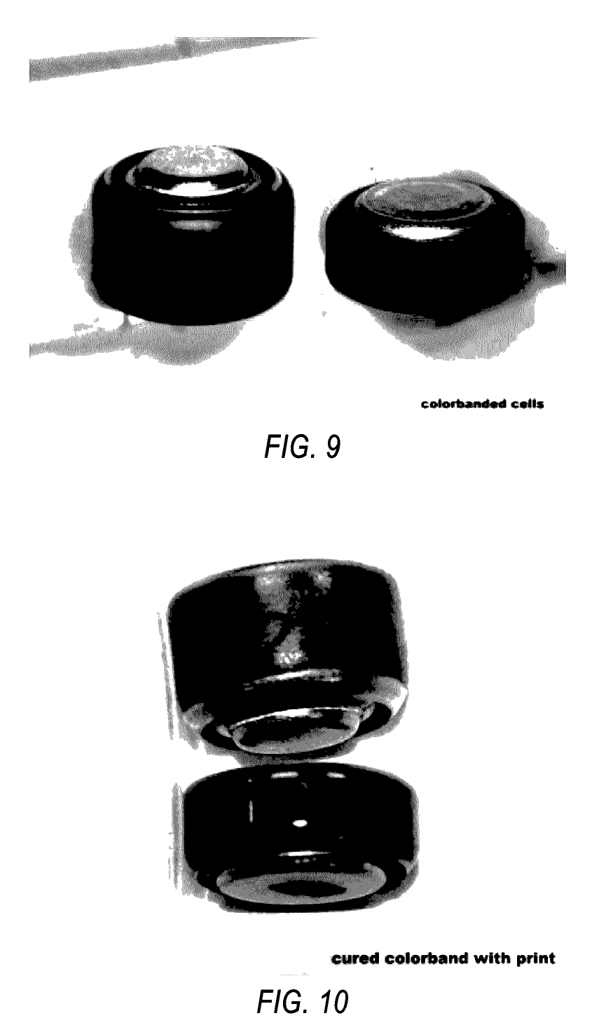

Once the coating process was completed, lot codes were printed onto each cell using an ImTech inkjet printer using ImTech IS411 black ink. The coated cell was then rotated in front of the UV light under a flow of nitrogen for 10-40 seconds to cure the polymer material. A Dymax Blue Wave 200 with liquid wand was used for UV radiation. The inert gas minimizes the oxygen inhibition that is common in UV cured epoxies. Final products, i.e., the coated and printed batteries are illustrated in FIGS. 9 and 10.

Preparation of Green Tint Evercoat Pre-Mix:

Evercoat color agent yellow 100505 (76% by weight), Evercoat color agent blue 100507 (18% by weight) and Evercoat color agent white 100509 (6% by weight) were mixed in a container using a FlackTek SpeedMixer DAC150FVZ operated at 2000 rpm for 2 minutes to obtain a green tint Evercoat pre-mix.

### Durability Testing for Polymer Coatings

### Example 2

### Control Polymer Coating

Dymax 728G (90% by weight) was mixed with green tint Evercoat pre-mix (10%) using a FlackTek SpeedMixer DAC150FVZ operated at 2000 rpm for 2 minutes. This mixture was then loaded into a syringe dispenser (Fishman LDS9000 airless applicator) and applied to the rotating cell under a layer of inert gas (N₂) using the automated apparatus illustrated in FIG. 8. The polymer material was shaped and smoothed, using wipe material (Scotch Magic tape from 3M with a sticky side up), to obtain the requisite cell diameter. As the cell was rotated, wipe material was pulled away from the cell. A lot code was then printed onto the coated cell with an ImTech inkjet printer using ImTech IS411 black ink. The coated cell was then rotated in front of the UV light in the presence of nitrogen for 20 seconds to cure the polymer material. A Dymax Blue Wave 200 with liquid wand was used as the UV radiation source.

### Example 3

### Test Polymer Coating 1

Dymax 730BT (90% by weight) was mixed with green tint Evercoat pre-mix (10%) using a FlackTek SpeedMixer DAC150FVZ operated at 2000 rpm for 2 minutes. This mixture was then loaded into a syringe dispenser (Fishman LDS9000 airless applicator) and applied to the rotating cell under a layer of nitrogen using the automated apparatus illustrated in FIG. 8. The polymer material was shaped and smoothed, using wipe material (Scotch Magic tape from 3M with a sticky side up), to the requisite diameter. As the cell was rotating, the wipe material was pulled away from the cell to remove excess polymer material. A lot code was then printed onto the coated cell with an ImTech inkjet printer using ImTech IS411 black ink. The cell was then rotated in front of the UV lamp light guide, in the presence of an inert gas (N₂) for 20 seconds, to cure the coating. A Dymax Blue Wave 200 with liquid wand was used as the UV radiation source.

### Example 4

### Test Polymer Coating 2

In a container Dymax 730BT (90% by weight) was mixed with green tint Evercoat pre-mix (10% by weight) using a FlackTek SpeedMixer DAC150FVZ operated at 2000 rpm for 2 minutes to give 730BTₜᵢₙₜ. In another container Dymax OP-4-20632 (90% by weight) was mixed with green tint Evercoat pre-mix (10% by weight) tint using a FlackTek SpeedMixer DAC150FVZ operated at 2000 rpm for 2 minutes to give OP4-20632ₜᵢₙₜ. In the next step, 730BTₜᵢₙₜ (40% by weight), OP4-20632ₜᵢₙₜ (40% by weight), and Dymax 728G (20%) were mixed using a FlackTek SpeedMixer DAC150FVZ operated at 2000 rpm for 2 minutes. The product was then loaded into a syringe dispenser (Fishman LDS9000 airless applicator) and applied to the rotating cell under a layer of nitrogen using the automated apparatus illustrated in FIG. 8. The polymer material 70 was shaped and smoothed using wipe material (Scotch Magic tape from 3M with a sticky side up), to the requisite diameter. As the cell rotated, the wipe material was pulled away from the cell. A lot code was then printed onto the coated cell with an ImTech inkjet printer using ImTech IS411 black ink. The cell was then rotated in front of the UV light under a flow of nitrogen for 20 seconds, to cure the coating. A Dymax Blue Wave 200 with liquid wand was used as the UV radiation source.

### Example 5

### Test Polymer Coating 3

In a container, tetraethylene glycol dimethacrylate (83% by weight) was mixed with 2,2-dimethoxy-2-phenylacetophenone (17% by weight) using a FlackTek SpeedMixer DAC150FVZ operated at 2000 rpm for 2 minutes. The resulting product was a homogeneous solution. The resulting product (3.2%), Dymax 730BT (34.8% by weight), Dymax OP-4-20632-G (34.8% by weight), Loctite 3494 (19.4%), and green tint Evercoat pre-mix (7.8% by weight) were then mixed using a FlackTek SpeedMixer DAC150FVZ operated at 2000 rpm for 2 minutes. This mixture was then loaded into a syringe dispenser (Fishman LDS9000 airless applicator) and applied to the rotating cell under a layer of nitrogen using the automated apparatus illustrated in FIG. 8. The polymer material 70 was shaped and smoothed, using wipe material (Scotch Magic tape from 3M with a sticky side up), to the desired diameter. As the cell rotated, excess polymer material 70 was pulled away from the cell. A lot code was then printed onto the coated cell with an ImTech inkjet printer using ImTech IS411 black ink. The cell was then rotated in front of the UV lamp under the flow of nitrogen for 40 seconds to cure the polymer material coating. A Dymax Blue Wave 200 with liquid wand was used as the UV radiation source.

### Example 6

### Test Polymer Coating 4

In a container N,N-dimethylacrylamide (83% by weight) was mixed with 2,2-dimethoxy-2-phenylacetophenone (17% by weight) using a FlackTek SpeedMixer DAC150FVZ operated at 2000 rpm for 2 minutes, resulting in the formation of a homogeneous resulting solution. The resulting solution (1%), Dymax 730BT (89.1% by weight), and green tint Evercoat pre-mix (9.9% by weight) were mixed using a FlackTek SpeedMixer DAC150FVZ operated at 2000 rpm for 2 minutes. The formulation was then loaded into a syringe dispenser (Fishman LDS9000 airless applicator) and applied to the rotating cell under a layer of nitrogen using the automated apparatus illustrated in FIG. 8. The polymer material was shaped and smoothed, using wipe material (Scotch Magic tape from 3M with a sticky side up), to the desired diameter. As the cell was rotating, excess polymer material was pulled away from the cell. A lot code was then printed onto the coated cell with an ImTech inkjet printer using ImTech IS411 black ink. The coated cell was then rotated in front of the UV lamp under a constant stream of nitrogen for 40 seconds to cure the coating. A Dymax Blue Wave 200 with liquid wand was used as the UV radiation source.

### Example 7

### Test Polymer Coating 5

In a container, tetraethylene glycol dimethacrylate (83% by weight) was mixed with 2,2-dimethoxy-2-phenylacetophenone (17% by weight) using a FlackTek SpeedMixer DAC150FVZ operated at 2000 rpm for 2 minutes to yield a homogeneous resulting solution. The resulting solution (7.5%), Dymax OP-4-20632-G (83.3% by weight), and green tint Evercoat pre-mix (9.2% by weight) were mixed using a FlackTek SpeedMixer DAC150FVZ operated at 2000 rpm for 2 minutes. This formulation was then loaded into a syringe dispenser (Fishman LDS9000 airless applicator) and applied to the rotating cell under a layer nitrogen using the automated apparatus illustrated in FIG. 8. The polymer material was shaped and smoothed, using wipe material (Scotch Magic tape from 3M with a sticky side up), to obtain a coated cell with a desired diameter. As the cell was rotating, the wipe material and excess polymer materials was pulled away from the cell. A lot code was then printed onto the coated cell with an ImTech inkjet printer using ImTech IS411 black ink. The cell was then rotated in front of the UV lamp in the presence of nitrogen gas for 20 seconds to cure the coating. A Dymax Blue Wave 200 with liquid wand was used as the UV radiation source.

### Example 8

### Durability Assessment of Polymer Coating in the Presence of Isopropyl Alcohol

A solution of isopropyl alcohol in deionized water was prepared by mixing semiconductor grade isopropyl alcohol (80%) with distilled water (20%). The solution was stirred until it was homogeneous, and then allowed to sit for 30 minutes. Batteries coated with the experimental polymer coatings were placed in a Pyrex dish with a sufficient volume of the 80% IPA solution so that the batteries were immersed in the solvent. A control battery cell, also immersed under the same conditions, was prepared using the polymer coating as described in Example 2. The isopropyl alcohol solution was kept at least 0.125 in. over the top of the coated cells and additional solvent was added as needed.

The Pyrex dish was kept at ambient temperature and the cells were monitored at predetermined intervals. Pictures were taken of each submerged cell at 3 minutes, 5 minutes, 30 minutes, 1 hour, 3 hours, 4 hours, 6 hours, 8 hours and 24 hours after immersion and observations were recorded at each time point. If the coating showed substantial swelling or separation from the metallic surface of the battery, the test coating was graded as “Fail”. If the coating showed slight discoloration but no swelling or separation from the metallic surface of the battery, the test coating was graded as “Good”. If the test coating showed substantially discoloration and/or slight separation from the metallic surface of the battery, the test coating was graded “Fair”. In addition, if the test coating showed no discoloration or separation from the metallic battery surface, the test coating was graded “Excellent.” The results obtained from these experiments are shown in Table 1.

TABLE 1
Durability observations for polymer coatings in 80% IPA.

| Polymer Coating | Time | | Result |
|---|---|---|---|
| Ex. 2 | 3 | minutes | Good |
| Ex. 2 | 30 | minutes | Fail |
| Ex. 2 | 24 | hours | Fail |
| Ex. 5 | 3 | minutes | Excellent |
| Ex. 5 | 6 | hours | Good |
| Ex. 5 | 24 | hours | Good |
| Ex. 7 | 3 | minutes | Excellent |
| Ex. 7 | 12 | hours | Good |
| Ex. 7 | 24 | hours | Fair |

### Example 9

### Durability Assessment of Polymer Coatings in the Presence of Solatec 70 SPF Sunscreen Lotion

A group of cells previously coated with experimental polymer coatings were placed in a Pyrex dish and Solatec 70 SPF sunscreen lotion (CVS®) was poured into the Pyrex dish so that the cells were immersed in the lotion. The Pyrex dish was placed into an oven at a temperature of 50° C. If necessary, additional amounts of Solatec 70 SPF sunscreen lotion were added to maintain the immersion of the cells in the sunscreen lotion. Observations were recorded at 3 minutes, 5 minutes, 30 minutes, 1 hour, 3 hours, 4 hours, 6 hours, 8 hours and 24 hours and pictures were taken. For each observation, the suntan lotion was gently wiped away from each cell so that the coatings could be assessed for degradation. The cells were immersed in fresh sunscreen lotion after each observation.

If the coating showed substantial swelling or separation from the metallic surface of the battery, the test coating was graded as “Fail”. If the coating showed slight discoloration but no swelling or separation from the metallic surface of the battery, the test coating was graded as “Good”. If the test coating showed substantially discoloration and/or slight separation from the metallic surface of the battery, the test coating was graded “Fair”. In addition, if the test coating showed no discoloration or separation from the metallic battery surface, the test coating was graded “Excellent”. The results obtained from these experiments are shown in Table 2.

TABLE 2
Observations for polymer coatings
in Solatec 70 SPF sunscreen lotion.

| Polymer Coating | Time | | Result |
|---|---|---|---|
| Ex. 2 | 3 | minutes | Good |
| Ex. 2 | 30 | minutes | Fail |
| Ex. 2 | 12 | hours | Fail |
| Ex. 5 | 5 | minutes | Excellent |
| Ex. 5 | 12 | hours | Fair |
| Ex. 5 | 24 | hours | Poor |
| Ex. 7 | 3 | minutes | Excellent |
| Ex. 7 | 12 | hours | Good |
| Ex. 7 | 24 | hours | Good |

### Example 10

### Durability Assessment of Polymer Coating in the Presence of Soap Solution

A 10% soap solution in water was prepared by mixing Neutrad (Decon Labs Inc.) in distilled water. The mixture was stirred until homogeneous, and then allowed to sit for 30 minutes. The cells coated with experimental polymer coatings were placed in a Pyrex dish and 10% soap solution (as prepared above) was poured into the Pyrex dish to cover the polymer coating. Precaution was taken not to cover or completely immerse the cells in solution in order to avoid the shorting of the cells. The Pyrex dish was placed in an oven kept at a temperature of 50° C. If necessary, additional soap solution was added periodically to maintain a nearly constant level of soap solution in the Pyrex dish. Observations were made after 3 minutes, 5 minutes, 30 minutes, 1 hour, 3 hours, 4 hours, 6 hours, 8 hours, and 24 hours and pictures were recorded. The control polymer coating in this experiment was generated as described in Example 2.

If the coating showed substantial swelling or separation from the metallic surface of the battery, the test coating was graded as “Fail”. If the coating showed slight discoloration but no swelling or separation from the metallic surface of the battery, the test coating was graded as “Good”. If the test coating showed substantially discoloration and/or slight separation from the metallic surface of the battery, the test coating was graded “Fair”. In addition, if the test coating showed no discoloration or separation from the metallic battery surface, the test coating was graded “Excellent”. The results obtained from these experiments are shown in Table 3.

TABLE 3
Observations for polymer coatings in a Neutrad soap solution.

| Polymer Coating | Time | | Result |
|---|---|---|---|
| Ex. 2 | 3 | minutes | Good |
| Ex. 2 | 6 | hours | Good |
| Ex. 2 | 24 | hours | Fail |
| Ex. 5 | 5 | minutes | Excellent |
| Ex. 5 | 6 | hours | Excellent |
| Ex. 5 | 24 | hours | Good |
| Ex. 7 | 3 | minutes | Excellent |
| Ex. 7 | 12 | hours | Excellent |
| Ex. 7 | 24 | hours | Good |

### Example 11

### Ink Readability Assessment

Lot numbers were printed onto each of the polymer coatings described in Examples 2-7. These printed coatings were wiped with a Kimwipe that was dampened with isopropyl alcohol 1 or 50 times and the readability of the lot numbers was visually assessed. The control polymer coating in this experiment was generated as described in Example 2. If the printed lot numbers were observed to be substantially unreadable or completely unreadable, the test coating was graded as “Fail”. If the printed lot numbers were observed to be entirely readable and showed slight fading, discoloration, or scratching, the test coating was graded as “Good”. If the printed lot numbers were observed to be entirely readable and showed significant discoloration, fading, or scratching, the test coating was graded “Fair”. And, if the printed lot numbers were observed to be entirely readable and showed no discoloration, fading, or scratching, the test coating was graded “Excellent”. The results obtained from these experiments are shown in Table 4.

TABLE 4
Printability of polymer coatings.

| Color Band | Number of wipes | Result |
|---|---|---|
| Ex. 2 | 1 | Good |
| Ex. 2 | 50 | Fail |
| Ex. 5 | 1 | Excellent |
| Ex. 5 | 50 | Fair |
| Ex. 7 | 1 | Excellent |
| Ex. 7 | 50 | Good |

### Example 12

### Assessment of Thickness of the Coating on Cells

As outlined in the general procedure, the polymer coating formation was performed a number of times in an auto-run mode using a polymer coating apparatus described in the Examples above and depicted in FIG. 8. In order to assess the reproducibility of the cell coating thickness using this apparatus, the diameter of the cell was measured using a Starret micrometer (no. 796) on a SPI mount. For this experiment, the polymer coating as described in Example 2 was used. The thickness of the cells was measured manually and the diameter of the coated cells is tabulated in Tables 5 and 6 (diameter is recorded in inches). From the results, the thickness obtained was unexpectedly consistent with a standard deviation of only 0.0004 inches. Using this apparatus, the diameter of the cell could be maintained with a precision of up to 0.002 inches.

TABLE 5
Cell diameter (inches) for runs 1-7 using an automated process.

| Run 1 | Run 2 | Run 3 | Run 4 | Run 5 | Run 6 | Run 7 |
|---|---|---|---|---|---|---|
| 0.3090 | 0.3090 | 0.3090 | 0.3090 | 0.3090 | 0.3080 | 0.3085 |
| 0.3090 | 0.3085 | 0.3085 | 0.3090 | 0.3095 | 0.3095 | 0.3095 |
| 0.3090 | 0.3090 | 0.3085 | 0.3085 | 0.3080 | 0.3095 | 0.3095 |
| 0.3095 | 0.3095 | 0.3095 | 0.3095 | 0.3090 | 0.3085 | 0.3090 |
| 0.3085 | 0.3085 | 0.3085 | 0.3085 | 0.3090 | 0.3090 | 0.3090 |
| 0.3085 | 0.3085 | 0.3090 | 0.3095 | 0.3085 | 0.3085 | 0.3090 |
| 0.3085 | 0.3085 | 0.3085 | 0.3085 | 0.3090 | 0.3085 | 0.3090 |
| 0.3095 | 0.3095 | N/A | N/A | 0.3085 | 0.3085 | 0.3090 |
| 0.3090 | 0.3085 | 0.3085 | 0.3085 | 0.3090 | 0.3090 | 0.3090 |
| 0.3095 | 0.3085 | 0.3090 | 0.3090 | 0.3090 | 0.3090 | 0.3090 |
| 0.3090 | 0.3085 | 0.3090 | 0.3090 | 0.3090 | 0.3085 | 0.3085 |
| 0.3085 | 0.3085 | 0.3090 | 0.3090 | N/A | N/A | N/A |
| 0.3090 | 0.3088 | 0.3088 | 0.3089 | 0.3089 | 0.3088 | 0.3090 |
| 0.3085 | 0.3085 | 0.309 | 0.309 | 0.308 | 0.308 | 0.3085 |
| 0.3095 | 0.3095 | 0.31 | 0.31 | 0.31 | 0.31 | 0.3095 |

TABLE 6
Cell diameter (inches) for runs 8-14 using an automated process.

| Run 8 | Run 9 | Run 10 | Run 11 | Run 12 | Run 13 | Run 14 |
|---|---|---|---|---|---|---|
| 0.3090 | 0.3085 | 0.3085 | 0.3085 | 0.3085 | 0.3090 | 0.3095 |
| 0.3080 | 0.3085 | 0.3085 | 0.3095 | 0.3090 | 0.3080 | 0.3095 |
| 0.3090 | 0.3095 | 0.3085 | 0.3090 | 0.3090 | 0.3095 | 0.3085 |
| 0.3095 | 0.3095 | 0.3090 | 0.3095 | 0.3080 | 0.3090 | 0.3095 |
| 0.3090 | 0.3095 | 0.3085 | 0.3095 | 0.3090 | 0.3085 | 0.3095 |
| 0.3095 | 0.3085 | 0.3090 | 0.3090 | 0.3095 | 0.3100 | 0.3095 |
| 0.3085 | 0.3085 | 0.3095 | 0.3090 | 0.3090 | 0.3085 | 0.3085 |
| 0.3085 | 0.3095 | 0.3085 | 0.3090 | 0.3090 | 0.3085 | 0.3095 |
| 0.3085 | 0.3090 | 0.3090 | 0.3085 | 0.3085 | 0.3085 | 0.3090 |
| 0.3080 | 0.3090 | N/A | 0.3095 | 0.3095 | 0.3095 | 0.3085 |
| 0.3090 | 0.3090 | 0.3085 | 0.3085 | 0.3090 | 0.3090 | 0.3085 |
| 0.3090 | 0.3085 | 0.3085 | 0.3085 | 0.3085 | 0.3090 | 0.3095 |
| 0.3088 | 0.3090 | 0.3088 | 0.3090 | 0.3089 | 0.3089 | 0.3091 |
| 0.308 | 0.3085 | 0.3085 | 0.3085 | 0.308 | 0.308 | 0.3085 |
| 0.31 | 0.3095 | 0.3095 | 0.3095 | 0.3095 | 0.31 | 0.3095 |

The data in Tables 5 and 6 demonstrate that the automated polymer coating system described in Example 12 generates consistent polymer coatings over the course of numerous runs.

### OTHER EMBODIMENTS

All publications and patents referred to in this disclosure are incorporated herein by reference to the same extent as if each individual publication or patent application were specifically and individually indicated to be incorporated by reference. Should the meaning of the terms in any of the patents or publications incorporated by reference conflict with the meaning of the terms used in this disclosure, the meaning of the terms in this disclosure are intended to be controlling. Furthermore, the foregoing discussion discloses and describes merely exemplary embodiments of the present invention. One skilled in the art will readily recognize from such discussion and from the accompanying drawings and claims, that various changes, modifications and variations can be made therein without departing from the spirit and scope of the invention as defined in the following claims.

What is claimed is:

1. A method of coating at least a portion of a metallic battery housing with a polymer material coating, comprising:
applying a polymer material to an external surface of the metallic housing;
shaping the polymer material on the surface of the housing to form a coating on at least a portion of the external surface;
applying an ink to the coating; and
at least partially curing the coating by applying UV radiation to the coating;
wherein the polymer material comprises an epoxy resin, a cross-linking agent, and a photoinitiator; and wherein the ink is applied to the coating prior to or concurrent with the curing of the coating.

2. The method of claim 1, wherein the polymer material further comprises a tint.

3. The method of either of claim 1 or 2, wherein the epoxy resin comprises bisphenol A epoxy resin, bisphenol F epoxy resin, novolac epoxy resin, aliphatic epoxy resin, glycidylamine epoxy resin, or any combination thereof.

4. The method of any of claims 1-3, wherein the cross-linking agent comprises tetraethylene glycol dimethacrylate, N,N-dimethyl acrylamide, isobornyl acrylate, urethane methacrylate, hexanediol diacrylate, di-trimethylolpropane tetra-acrylate, bisphenol A epoxy acrylate, carboxylated polyester methacrylate, aliphatic urethane acrylate, poly(acrylonitrile-co-buradines)-dicarboxy, polybutadiene dicarboxy terminated, isooctyl acetate, poly(acrylic acid), aliphatic urethane acrylate oligomer, difunctional aliphatic urethane acrylate oligomer, urethane diacrylate oligomer blended with isobornyl acrylate, or any combination thereof.

5. The method of any of claims 1-4, wherein the photoinitiator comprises 2,2-dimethoxy-2-phenyl-acetophenone, 3,4-dimethylbenzophenone, 2-hydroxy-2-methyl-1-phenyl-propan-1-one, α-amino ketone, 1-hydroxy-cyclohexyl-phenyl ketone, benzophenone, benzoin ethyl ether, benzoin ethyl ether with cyclodextrin, or any combination thereof.

6. The method of any of claims 1-5, wherein the polymer material is applied to the metallic housing under a layer of inert gas.

7. The method of claim 6, wherein the inert gas is selected from the group consisting of nitrogen gas, argon gas, carbon dioxide gas, or any combination thereof.

8. The method of any of claims 1-7, further comprising rotating the housing about a central axis and applying the polymer material to the outer circumference of the rotating housing.

9. The method of claim 8, wherein the shaping of the polymer material comprises applying an edge to the polymer material on the rotating housing to shape the polymer material into a coating that covers at least a portion of the outer circumference of the housing.

10. The method of any of claims 1-9, wherein the ink is applied to the coating using an ink jet.

11. The method of any of claims 1-10, wherein the ink is applied to the polymer material before the coating is substantially cured.

12. The method of any of claims 1-11, wherein the UV radiation is applied to the coating for period of about 10 s to about 10 min.

13. The method of any of claims 1-12, wherein the UV radiation is applied to the coating for a period of about 15 s to about 1 min.

14. The method of any of claims 1-13, wherein the UV radiation is substantially free of UV-B or UV-C radiation.

15. The method of any of claims 1-14, wherein the polymer material further comprises a filler.

16. The method of claim 15, wherein the filler comprises silicone dioxide, calcium carbonate, calcium hydroxide, hydrophobic silica, bentonite, polyacrylic acid, sand, hydroxyethyl cellulose, methyl cellulose, dragonite, or any combination thereof.

17. The method of any of claims 1-16, wherein the polymer material further comprises an adhesion promoter.

18. The method of any of claims 1-17, wherein the polymer material further comprises a solvent.

19. The method of claim 18, wherein the solvent comprises diacetone alcohol, butylacetate, or any combination thereof.

20. The method of any of claims 1-19, wherein the ink comprises a color that contrasts with a color of the polymer material coating.

21. An apparatus for applying a polymeric coating to an external metallic surface of a battery housing comprising:
a rotator;
an applicator;
a reservoir that stores uncured polymer material and fluidly connects to the applicator;
a wiper comprising an edge;
a printer;
a UV lamp; and
a gas outlet,
wherein the rotator is configured to rotate the battery housing about a central axis; the wiper is movable with respect to the central axis and configured to shape polymer material that is applied to the surface of the battery housing; and the gas outlet is configured to generate a layer of inert gas between the applicator and the battery housing.

22. The apparatus of claim 21, wherein the applicator is movable with respect to the central axis and configured to apply polymer material to at least a portion of the battery housing.

23. The apparatus of claim 21 or 22, wherein the applicator is selected from the group consisting of a syringe, an extruder, a sprayer, a brush, a roller, and a sponge.

24. The apparatus of any of claims 21-23, wherein the applicator is configured to apply a bead of polymer material to the surface of the battery housing.

25. The apparatus of any one of claim 21-24, wherein the UV lamp, the reservoir, the applicator, or any combination thereof further comprises a radiation shield.

26. The apparatus of any of claims 21-25, wherein the wiper further comprises a wipe material.

27. The apparatus of claim 26, wherein the wipe material is disposed between the edge of the wiper and the battery housing.

28. The apparatus of either of claim 26 or 27, wherein the wipe material further comprises a woven or non-woven film.

29. The apparatus of any of claims 21-28, wherein the reservoir comprises a storage chamber that is substantially free of oxygen gas.

30. The apparatus of any of claims 21-29, wherein the printer is an ink jet printer.

31. An electrochemical cell comprising:
an anode comprising zinc;
a cathode comprising silver oxide;
an electrolyte comprising an alkali metal hydroxide;
a cylindrical metallic housing having a central axis and an outer circumference; and
a coating that covers at least a portion of the outer circumference of the housing,
wherein the coating is generated by
applying a polymer material to an external surface of the metallic housing;
shaping the polymer material on the surface of the housing to form a coating;
applying an ink to the coating; and
curing the coating under ultraviolet radiation,
wherein the polymer coating comprises an epoxy resin, a cross-linking agent, a photoinitiator, and a tint; and wherein the ink is applied to the coating prior to or concurrent with the curing of the coating.

32. The electrochemical cell of claim 31, wherein the electrochemical cell is a rechargeable electrochemical cell.
